(19) United States
(12) Patent Application Publication
(10) Pub. No.: US 2023/0216273 A1
(43) Pub. Date: Jul. 6, 2023

(54) DIFFUSE ILLUMINATION AND MULTIMODE ILLUMINATION DEVICES

(71) Applicant: NIL Technology ApS, Kongens Lyngby (DK)

(72) Inventors: Ulrich Quaade, Bagsvaerd (DK); Villads Egede Johansen, Copenhagen (DK); Akbar Samadi, Copenhagen (DK); Yuriy Elesin, Copenhagen (DK); Moritz Schmidlin, Zurich (CH); Martin Balimann, Zurich (CH); Robert Lenart, Rapperswil (CH); Tobias Senn, Zurich (CH); James Eilertsen, Zug (CH)

(21) Appl. No.: 18/008,889

(22) PCT Filed: Jun. 9, 2021
(86) PCT No.: PCT/EP2021/065498

§ 371 Date: Dec. 7, 2022

Related U.S. Application Data
(60) Provisional application No. 63/036,835, filed on Jun. 9, 2020.
(60) Provisional application No. 63/036,824, filed on Jun. 9, 2020.
(60) Provisional application No. 63/036,831, filed on Jun. 9, 2020.

(51) Int. Cl. H01S 5/042; H01S 5/42; H01S 5/183

(52) U.S. Cl. CPC H01S 5/042; H01S 5/423; H01S 5/18394; G01B 11/25

(57) ABSTRACT

Illumination modules are operable, in some implementations, to project a homogenous diffuse illumination onto a scene. Some implementations allow different subsets of light emitting elements to be addressed independently so that they can be turned on (or off) at different times, which can facilitate multi-mode operation.

### CROSS-REFERENCE TO RELATED APPLICATIONS

This application claims the benefit of priority of U.S. Provisional Pat. Application Nos. 63/036,824, 63/036,831 and 63/036,835, all filed on Jun. 9, 2020, the disclosures of which are incorporated herein by reference in their entirety.

### FIELD OF THE DISCLOSURE

The present disclosure relates to diffuse illumination and multimode illumination devices.

### BACKGROUND

Some optical imaging systems are capable of providing distance measurements and/or a depth image of objects within a capture area. Such systems can be used, for example, to generate proximity data, distance data, or three-dimensional data.

An imaging system can include, for example, a projector having a light source for illuminating a scene, as well as a sensing device (e.g., one or more cameras) for receiving light reflected from the objects in the scene. In some cases, the light source includes a vertical-cavity surface-emitting laser (VCSEL) array, which is operable to illuminate a capture area. Depending on the implementation and requirements of the imaging system, the projector may be designed to produce substantially diffuse light (i.e., light with a relatively large angular spread) to be projected onto the scene. In other cases, the projector may be designed to produce light having substantially discrete features, such as a structured-light pattern or projected texture, to be projected onto the scene. In either case, light from the VCSEL array may be reflected off of one or more objects in the capture area and can be received within the sensing device. The reflected light may be detected by the one or more cameras and then analyzed, for example, to determine proximity, distance or other information.

### SUMMARY

The present disclosure describes illumination modules that are operable, in some implementations, to project a homogenous diffuse illumination onto a scene. Some implementations allow different subsets of light emitting elements to be addressed independently so that they can be turned on (or off) at different times, which can facilitate multi-mode operation.

In one aspect, for example, the present disclosure describes an apparatus including a light source, one or more optical elements, and control circuitry. The light source includes a first subset of light emitting elements and a different second subset of light emitting elements. Each of the light emitting elements of the first subset is operable to produce a respective light beam, and each of the light emitting elements of the second subset is operable to produce a respective light beam that is less diffuse than the light beams produced by the first subset of light emitting elements. The one or more optical elements are disposed so as to project the light beams produced by the first and second subsets of light emitting elements onto a scene. The control circuitry is operable to control respective durations for which the light emitting elements of the first and second subsets are on so that a resulting overall illumination projected onto the scene is substantially homogenous diffuse illumination.

Some implementations include one or more of the following features. For example, in some cases, the light emitting elements of the first and second subsets, and the one or more optical elements, are disposed such that the light beams produced by the second subset are projected onto the scene so as to at least partially fill gaps in illumination produced by the first subset of light emitting elements. In some cases, the control circuitry is operable to turn on the light emitting elements of the first subset for a first duration, and to turn on the light emitting elements of the second subset for a second duration while the light emitting elements of the first subset are on, wherein the second duration is shorter than the first duration. In some implementations. each of the first and second subsets of light emitting elements is composed of VCSELs. The VCSELs of the first subset can have a first aperture, and the VCSELs of the second subset can have a second aperture, wherein the first aperture is larger than the second aperture. In some cases, the VCSELs of the first subset have a rectangular (e.g., square) aperture or a hexagonal aperture. In some cases, the VCSELs of the first subset have an aperture shaped differently from a shape of an aperture of the VCSELs of the second subset.

In some implementations, the control circuitry is operable to turn on the second subset of light emitting elements in a second mode of operation to project, for example, a structured light pattern onto the scene.

The present disclosure also describes a method that includes turning on a first subset of light emitting elements (e.g., VCSELs) and projecting diffuse illumination onto a scene using light produced by the first subset of light emitting elements, and employing temporal light stitching to at least partially fill gaps in the diffuse illumination by turning on a second subset of light emitting elements (e.g., VCSELs) and projecting light produced by the second subset of light emitting elements onto the scene. The second subset of light emitting elements is on for a shorter duration than the first subset of light emitting elements.

In some implementations, the method further includes turning on a third subset of light emitting elements (e.g., VCSELs) and projecting light produced by the third subset of light emitting elements onto the scene. The third subset of light emitting elements is on for a duration shorter than the first subset of light emitting elements, and the light produced by the third subset and projected onto the scene at least partially fills additional gaps in the diffuse illumination. In some instances, the third subset of light emitting elements is on for a duration that differs from the duration for which the second subset of light emitting elements in on.

The present disclosure also describes an apparatus that includes an array of VCSELs, and one or more optical elements. Each of the VCSELs has a rectangular or hexagonal aperture, and each of the VCSELs being operable to produce a respective light beam. The one or more optical elements are disposed so as to project the light beams onto a scene. For a particular working distance, when the VCSELs in the array are on, a substantially gap-free homogenous diffuse illumination is projected onto the scene.

In some implementations, each of the VCSELs has a square aperture or a hexagonal aperture. In some instances, for the particular working distance, when the VCSELs in the array are on, there is no overlap between individual light beams produced by different ones of the VCSELs and projected onto the scene.

Some implementations include one or more of the following advantages. For example, a more homogenous diffuse illumination can be projected onto a scene in some instances. Further, various implementations allow different subsets of light emitting elements (e.g., VCSELs) to be addressed independently so that they can be turned on (or off) at different times, which can facilitate multi-mode operation. For example, in one mode, substantially diffuse illumination may be projected onto a scene, whereas in a second mode, a structured light pattern may be projected onto a scene.

Other aspects, features and advantages will be readily apparent from the following detailed description, the accompanying drawings, and the claims.

### BRIEF DESCRIPTION OF THE DRAWINGS

FIGS. 1A and 1B illustrate an example of an illumination module.

FIG. 2 illustrates another example of an illumination module.

FIGS. 3A and 3B illustrate a further example of an illumination module.

FIG. 4 illustrates another example of an illumination module.

FIG. 5 illustrates yet another example of an illumination module.

FIG. 6 illustrates an example of structured-light illumination.

FIG. 7 illustrates an example of diffuse illumination.

FIGS. 8A and 8B illustrate examples of illuminations produced by light emitting elements having circular apertures.

FIG. 9A is a graph illustrating an example of temporal light stitching.

FIG. 9B illustrates an example of the resulting illumination for the scenario of FIG. 9A.

FIG. 10A illustrates an example of gap-free homogenous diffuse illumination on a scene using light emitting elements having a hexagonal aperture.

FIG. 10B illustrates an example of the gap-free homogenous diffuse illumination on a scene using light emitting elements having a square aperture.

FIG. 11A illustrates an example of illumination produced using a first array of light emitting elements.

FIG. 11B illustrates an example of illumination produced using two different subarrays of light emitting elements.

FIG. 12 illustrates an example of illustrates an example of an illumination module that includes three different subarrays of light emitting elements.

FIG. 13 is a flow chart of a method in accordance with some implementations.

### DETAILED DESCRIPTION

One aspect of this disclosure describes multimode illumination devices that can be incorporated, for example, into an imaging system. Such illumination devices are operable in multiple modes. For example, in some implementations, a multimode illumination device can be operated in a first mode to generate a first illumination and a second mode to generate a second illumination that is different from the first illumination.

As an example, in the first mode, the first illumination can be substantially diffuse light (i.e., light with a relatively large angular spread), whereas in the second mode, the illumination can include substantially discrete features, such as a structured-light pattern or projected texture, which can be useful for active stereo applications. In some instances, the first mode can be used, in combination with one or more cameras (e.g., a 3D camera and a RGB camera) to generate proximity or distance data, and the second mode can be used, in combination with the same or different cameras, to generate three-dimensional data or spectral data. The light sensitive device(s) can include, for example, a photodiode, an array of photodiodes, an image sensor, or a time-of-flight sensor.

In some implementations, multimode illumination modules can provide certain advantages. For example, multimode illumination modules may need a smaller footprint than two modules, each of which is configured to generate one of the two or more functions provided by the multimode illumination modules.

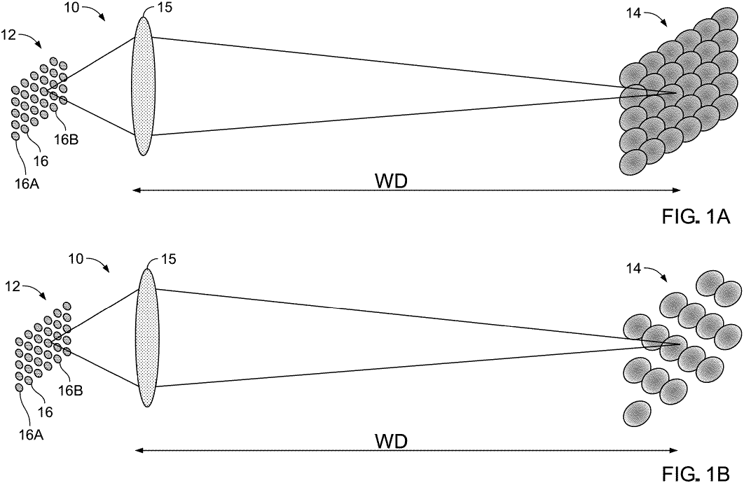

As shown in the example of FIGS. 1A and 1B, an illumination module 10 includes a light source 12 for illuminating a scene 14. The module 10 also may include one or more lenses or other optical elements 15 operable, for example, to focus or collimate the light emitted by the light source 12. In some instances, the optical elements 15 include a micro-lens array or metalens array.

The light source 12 includes multiple light emitting elements, such as an array of VCSELs 16, which are operable to illuminate the scene. The VCSELs 16 are independently addressable. That is, individual VCSELs 16 (or subsets of VCSELs) can be turned on or off independently of other individual VCSELs (or subsets of VCSELs). In particular, the VCSEL array includes two or more VCSEL subarrays, which may be operated at the same time (i.e., the VCSELs in the subsarrays may produce optical emissions substantially at the same time) or which may be operated separately from each other (e.g., sequentially).

FIGS. 1A and 1B illustrate an example having two different subarrays of VCSELs 16. That is, each VCSEL 16 in the array is part of a first subarray or a second subarray. In the illustrated example, a VCSEL 16A is part of the first subarray, whereas a VCSEL 16B is part of the second subarray. As indicated by FIG. 1A, when the VCSELs of both subarrays are turned on at the same time, a substantially diffuse illumination is produced on a plane at a working distance (WD). On the other hand, when only a subset of the VCSELs (e.g., only the VCSELs in the second array) are turned on, as shown in FIG. 1B, a pattern of dots is produced on the plane at the working distance (WD). The dot pattern may be a regular or irregular (i.e., random) pattern of dots, which may be used, for example, to provide for structured illumination. For example, in some instances, the light beams may form a grid pattern or a strip pattern for structured light imaging techniques.

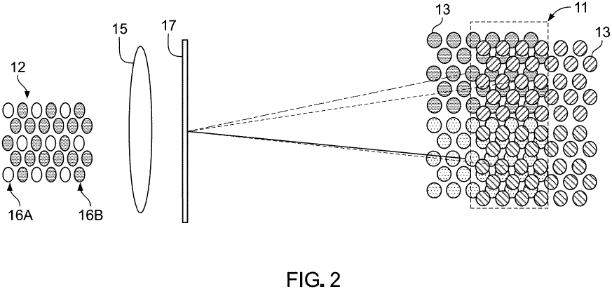

In some cases, as shown in FIG. 2, the illumination module also includes a fan-out diffractive optical element (DOE) 17. The fan-out DOE 17 can be operable to replicate the image of the VCSEL array, and to shift each replicated image by an amount less than the size of the image. This results in overlapping images of the VCSELs that are turned on. Even when the VCSELs of both subarrays are turned on, the resulting diffuse light pattern 11 projected onto the scene will be surrounded by dots 13 along the border of the diffuse light pattern because, at the border, the pattern does not overlap. On the other hand, by turning on only one of the subsets of VCSELs at a particular time, a dot pattern can be projected onto the scene.

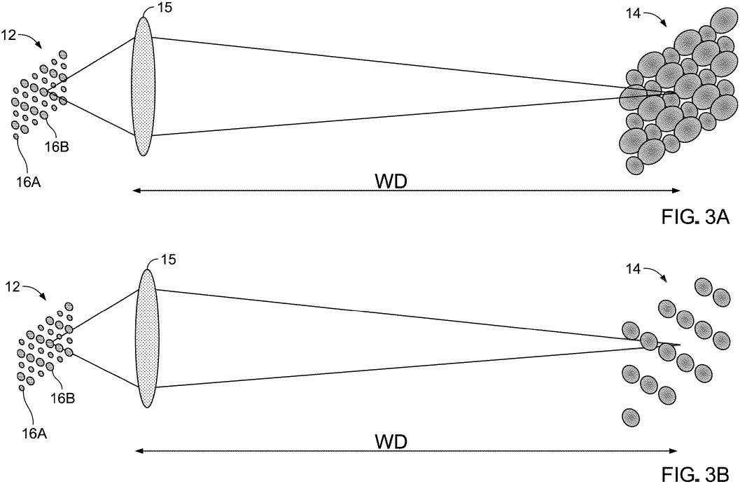

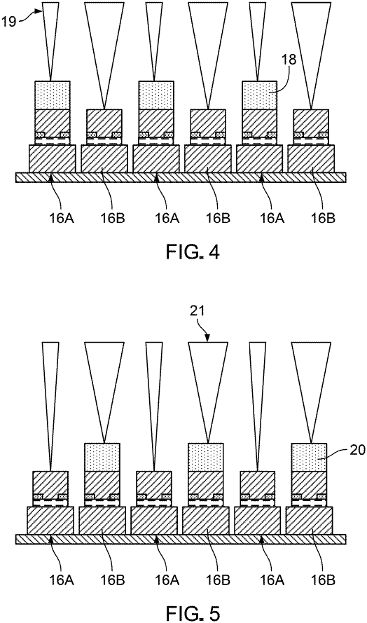

In some implementations, the VCSELs or other light emitting elements 16 in each of the subarrays may have different sizes. For example, as shown in FIGS. 3A and 3B, VCSELs in the first subarray (e.g., the VCSEL 16A) may have a relatively small aperture, whereas VCSELs in the second subarray (e.g., the VCSEL 16B) may have a relatively large aperture. Light emitted by the smaller VCSELs in the first subarray may produce a circular dot of light that is smaller, and sharper, than that produced by the larger VCSELs in the second subarray. Thus, as indicated by FIG. 3A, when the VCSELs of both subarrays are turned on at the same time, a substantially diffuse illumination is produced on a plane at a working distance (WD) from the VCSEL array. On the other hand, when only a subset of the VCSELs (e.g., only the smaller VCSELs in the first array) are turned on, as shown in FIG. 3B, a pattern of dots is produced on the plane at the working distance (WD) from the VCSEL array. The dot pattern may be a regular or irregular (i.e., random) pattern of dots, which may be used, for example, to provide for structured illumination.

In some implementations, instead of – or in addition to – the subarrays having VCSELs of different sizes, each of the VCSELs 16 in one of the subarrays includes an integrated optical element through which the light produced by the VCSEL passes. For example, as shown in FIG. 4, each of the VCSELs 16A in the first subarray includes an integrated lens 18 through which the light produced by the VCSEL passes. The light produced by each of the VCSELs 16A in the first subarray is a relatively sharp spot 19 so that the light produced collectively by the VCSELs in the first subarray is a pattern of relatively sharp dots. The other VCSELs 16B, which are part of the second subarray, do not include such an integrated lens 18, and can be used, for example, to produce substantially diffuse light. The VCSELs in the different subarrays can be turned on or off independently and at different times so that the module can be operated in different modes to provide different types of illumination at different times. For example, by turning on only one of the VCSEL subarrays at a time, the module can be operated, for example, to produce diffuse light or a dot pattern.

Likewise, as shown in the example of FIG. 5, each of the VCSELs 16B in the second subarray includes an integrated a block of high refractive index material 20 through which the light produced by the VCSEL passes. The light 21 produced by the VCSELs 16B in the second subarray is substantially diffuse light. The other VCSELs, which are part of the first subarray, do not include such a block of high refractive index material 20. The VCSELs in the different subarrays can be turned on or off independently and at different times so that the module can be operated in different modes to provide different types of illumination at different times.

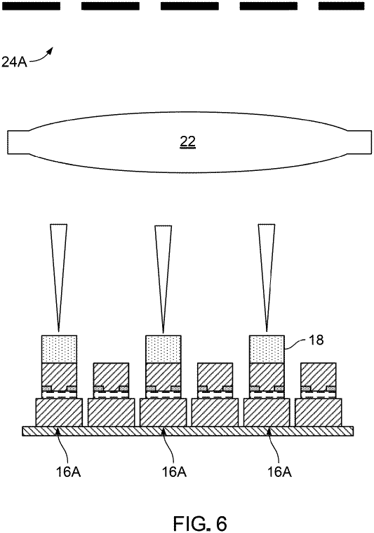

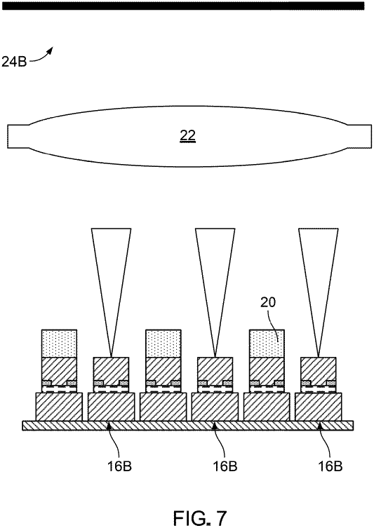

In some implementations, as shown in the examples of FIGS. 6 and 7, supplemental optics 22 can be disposed so as to intersect the path of light emitted by the VCSELs. The supplemental optics 22 can be used, for example, to focus or collimate the light toward a scene. FIG. 6 illustrates an example that produces structured-light illumination 24A when only the first subarray of VCSELs 16A is turned on, whereas FIG. 7 illustrates an example that produces substantially diffuse illumination 24B when only the second subarray of VCSELs 16B is turned on.

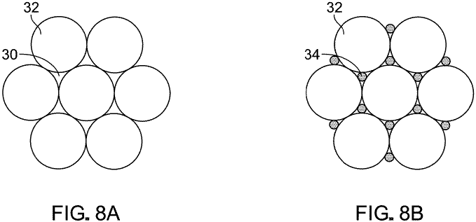

In some implementations, the VCSELs 16 have circular apertures. Thus, the light output by an individual VCSEL 16 will appear as a dot (i.e., a circle) when projected onto a plane that is perpendicular to the direction of light emission. As indicated by FIG. 8A, even when VCSELs having a circular aperture and a given size are packed in an array as densely as possible, the projected diffuse light pattern may have small gaps 30 between the circular dots 32 of light that appear on the illuminated scene. To obtain a more homogenous diffuse pattern of light, a second subarray of VCSELs having a smaller circular aperture can be included in the VCSEL array (see, e.g., FIG. 3A) such that, as indicted by FIG. 8B, the light emitted by the VCSELs of the second subarray results in small dots 34 of light that at least partially fill the gaps 30. Thus, when the VCSELs of both subarrays are on at the same time, the result can be a more homogenous diffuse pattern of light projected onto the scene.

On the other hand, turning on the VCSELs having the smaller aperture at the same time and for the same duration as the VCSELs having the larger aperture can result in bright spots appearing in the image plane. That is because the light emitted by each respective one of the VCSELs having the smaller aperture will be focused on a smaller area than the light emitted by each respective one of the VCSELs having a larger aperture.

The following paragraphs describe various approaches for projecting a more homogenous diffuse onto a scene.

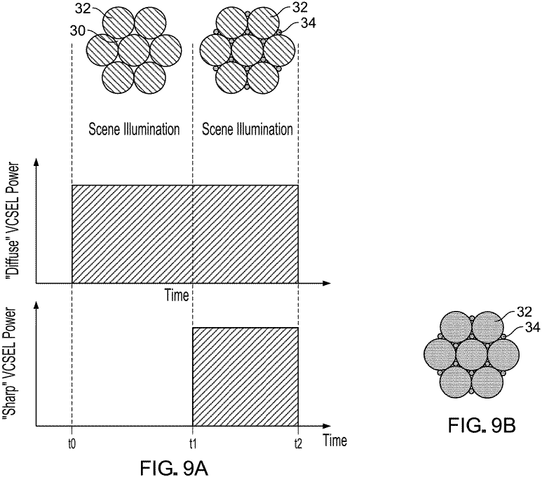

In accordance with a first approach, temporal light stitching is employed to fill gaps in the diffuse illumination. That is, the VCSELs having the smaller aperture (and resulting in a sharper, brighter spot) are turned on for a shorter duration that the VCSELs having the larger aperture (that provide relatively diffuse illumination). The period during which the two subarrays of VCSELs are on overlaps, but only partially. The duration for which the VCSELs having the smaller aperture are turned on is chosen such that the total optical power per area projected onto the scene by VCSELs having the smaller aperture is substantially the same as the total optical power per area projected onto the scene by VCSELs having the larger aperture. This scenario is illustrated in FIG. 9A, where the shaded areas in the graphs plotting power versus time indicate periods when the respective VCSELs are on (i.e., emitting light). Thus, from time t0 until time t1, only the diffuse illumination VCSELs having the larger aperture are on. Then, from time t1 until time t2, the VCSELs having the smaller aperture (and emitting greater optical power per unit area per time) also are on. FIG. 9B illustrates the total optical power projected onto areas of an image plane, which indicates that a more homogenous illumination can be achieved and such that the illuminated region has fewer and/or smaller gaps.

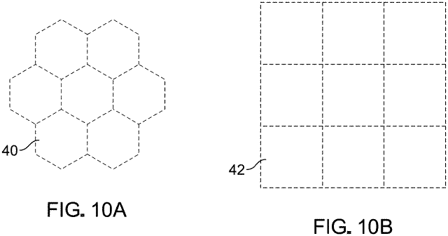

In accordance with a second approach, instead of circular apertures, each VCSEL in one of the subarrays of the light source can have a rectangular (e.g., square) or hexagonal shape. This approach allows each respective light beam projected onto the scene to have a particular beam-waist such that a smooth stitching (gap-free illumination) can be designed for a fixed working distance (or working distance range). Further, at the particular working distance, there is little or no overlap in the individual light beams projected onto the scene. Thus, the resulting diffuse illumination can be highly uniform or homogenous. FIG. 10A illustrates an example of the resulting gap-free homogenous diffuse illumination on a scene when each VCSEL has a hexagonal aperture. In this cases, each VCSEL projects a light beam 40 onto the scene having a substantially hexagonal shape. FIG. 10B illustrates an example of the resulting gap-free homogenous diffuse illumination on a scene when each VCSEL has a square aperture. In this cases, each VCSEL projects a light beam 42 onto the scene having a substantially square shape.

In some implementations, the foregoing approach can be integrated into a multi-mode device. For example, in a first mode, a first subset of VCSELs having a rectangular or hexagonal shaped aperture can be turned on to project a substantially gap-free diffuse illumination onto a scene, whereas in a second mode, a second subset of VCSELs, each of which has a relatively small circular aperture, can be turned on (while the first subset of VCSELs is off) to project a structured light pattern onto a scene.

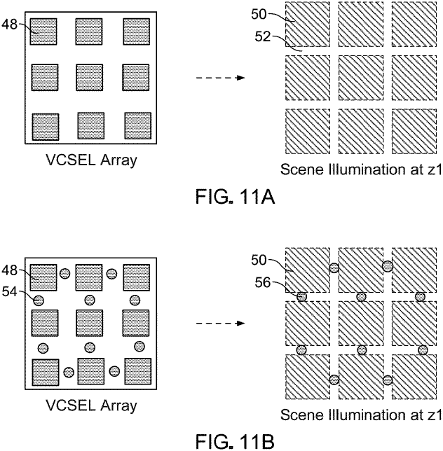

In some cases, features of the first and second approaches may be combined. Such an implementation can be advantageous, for example, when the object(s) in a scene to be illuminated are outside the ideal operational working range for which the hexagonal or rectangular array is optimized. For example, if the object(s) is outside the ideal working range (e.g., at a large distance z1), then there may be gaps 52 between the individual illuminated regions 50 on the scene that are illuminated by the VCSELs 48 having square aperture (see FIG. 11A). In that case, it can be advantageous to have a second subset of VCSELs 54 (e.g., VCSELs having a relatively small circular aperture), which can be turned on for a shorter duration than the VCSELs having a rectangular or hexagonal shaped aperture to obtain a more homogenous illumination. The “sharp” VCSELs 54 are configured to patch areas of the diffuse illumination 50 by providing illumination 56 in the gaps 52 (see FIG. 11B).

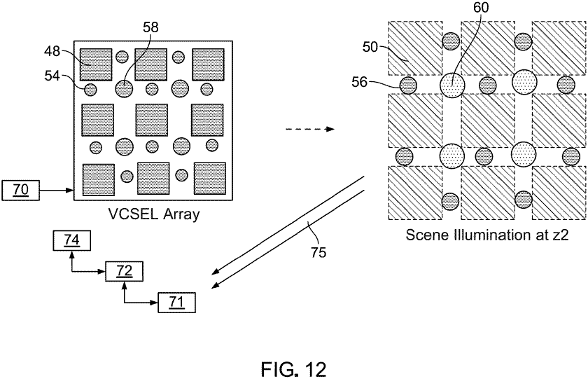

Further, in some implementations, the light source can include more than two subsets (e.g., subarrays) of VCSELs. As shown in the example of FIG. 12, a first subarray is composed of VCSELs 48 that have a square aperture and illuminate regions 50 of a scene at a distance z2. In some cases, the VCSELs 48 may have hexagonal or circular apertures. A second subarray is composed of VCSELs 54 that have a circular aperture of diameter d1 and that illuminate regions 56 of the scene. A third subarray is composed of VCSELs 58 that have a diameter d2 (where d2 > d1) and that illuminate regions 60 of the scene. The different subarrays can be addressed, and thus turned on (or off), independently of one another. The VCSELs 54, 58 of the second and third subarrays are designed and positioned so that the regions 56, 60 illuminated, respectively, by the second and third subarrays at least partially fill gaps in the diffuse illumination produced by the first subarray of VCSELs 48. The respective durations for which the VCSELs 54, 58 of the second and third subarrays are turned on can be controlled (e.g., by appropriate control circuitry 70) so that the resulting illumination projected onto the scene is more uniform (i.e., more homogenous), without significant bright spots occurring. The durations for which the respective VCSELs 54, 58 of the second and third arrays are on may be the same or may differ. Thus, the VCSELs can be turned on for durations so that the overall illumination projected onto the scene by all the subsets of VCSELs 48, 54, 58 in combination is a highly uniform and homogenous diffuse illumination.

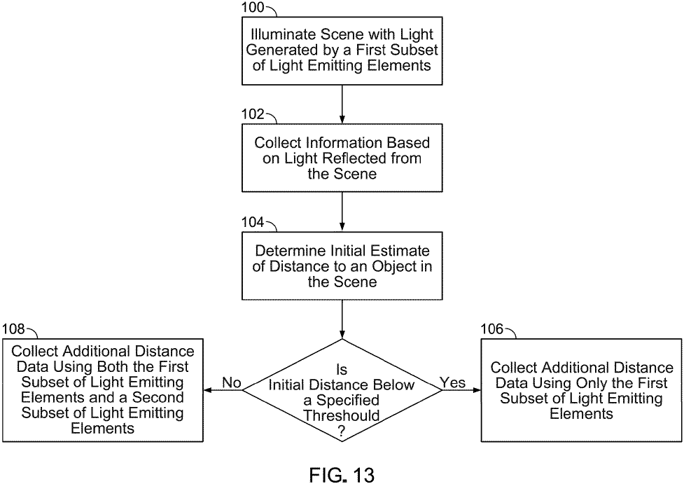

As indicated by FIGS. 12 and 13, in some instances, the scene may be illuminated with a first subset of the light emitting elements (e.g., the “sharp” VCSELs 54 and/or 58) (block 100), initial information based on light 75 reflected from the scene may be collected (e.g., by an image sensor 71 and read-out circuitry 72) (block 102), and an initial estimate of distance can be determined (e.g., by processing circuitry 74) (block 104). If the initial estimate of distance indicates an object of interest is below a specified threshold distance, then distance data may be collected with the “sharp” VCSELs 54, 58 only (block 106). On the other hand, if the initial estimate of distance indicates an object of interest is at, or above, the threshold distance, then distance data may be collected using a second subset of the light emitting elements as well (e.g., the “diffuse” VCSELs 48 and the “sharp” VCSELs 54 and/or 58 on) (block 108).

In some instances, the various illumination modules described above may be formed as an integrated photonic package.

Various aspects of the subject matter and the functional operations described in this specification can be implemented in digital electronic circuitry, or in computer software, firmware, or hardware, including the structures disclosed in this specification and their structural equivalents, or in combinations of one or more of them. Thus, aspects of the subject matter described in this specification can be implemented as one or more computer program products, i.e., one or more modules of computer program instructions encoded on a computer readable medium for execution by, or to control the operation of, data processing apparatus. The computer readable medium can be a machine-readable storage device, a machine-readable storage substrate, a memory device, a composition of matter effecting a machine-readable propagated signal, or a combination of one or more of them. The apparatus can include, in addition to hardware, code that creates an execution environment for the computer program in question, e.g., code that constitutes processor firmware.

A computer program (also known as a program, software, software application, script, or code) can be written in any form of programming language, including compiled or interpreted languages, and it can be deployed in any form, including as a stand-alone program or as a module, component, subroutine, or other unit suitable for use in a computing environment. A computer program does not necessarily correspond to a file in a file system. A program can be stored in a portion of a file that holds other programs or data (e.g., one or more scripts stored in a markup language document), in a single file dedicated to the program in question, or in multiple coordinated files (e.g., files that store one or more modules, sub programs, or portions of code). A computer program can be deployed to be executed on one computer or on multiple computers that are located at one site or distributed across multiple sites and interconnected by a communication network.

The processes and logic flows described in this specification can be performed by one or more programmable processors executing one or more computer programs to perform functions by operating on input data and generating output. The processes and logic flows can also be performed by, and apparatus can also be implemented as, special purpose logic circuitry, e.g., an FPGA (field programmable gate array) or an ASIC (application specific integrated circuit).

Processors suitable for the execution of a computer program include, by way of example, both general and special purpose microprocessors, and any one or more processors of any kind of digital computer. Generally, a processor will receive instructions and data from a read only memory or a random access memory or both. The essential elements of a computer are a processor for performing instructions and one or more memory devices for storing instructions and data. Computer readable media suitable for storing computer program instructions and data include all forms of non-volatile memory, media and memory devices, including by way of example semiconductor memory devices, e.g., EPROM, EEPROM, and flash memory devices; magnetic disks, e.g., internal hard disks or removable disks; magneto optical disks; and CD ROM and DVD-ROM disks. The processor and the memory can be supplemented by, or incorporated in, special purpose logic circuitry.

While this specification contains many specifics, these should not be construed as limitations on the scope of the invention or of what may be claimed, but rather as descriptions of features specific to particular embodiments of the invention. Certain features that are described in this specification in the context of separate embodiments can also be implemented in combination in a single embodiment. Conversely, various features that are described in the context of a single embodiment can also be implemented in multiple embodiments separately or in any suitable sub-combination. Moreover, although features may be described above as acting in certain combinations and even initially claimed as such, one or more features from a claimed combination can in some cases be excised from the combination, and the claimed combination may be directed to a sub-combination or variation of a sub-combination.

Similarly, while operations are depicted in the drawings in a particular order, this should not be understood as requiring that such operations be performed in the particular order shown or in sequential order, or that all illustrated operations be performed, to achieve desirable results. In certain circumstances, multitasking and parallel processing may be advantageous.

Various modifications will be readily apparent and can be made to the foregoing examples. Accordingly, other implementations also are within the scope of the claims.

1. An apparatus comprising:
a light source including a first subset of light emitting elements and a different second subset of light emitting elements, wherein each of the light emitting elements of the first subset is operable to produce a respective light beam, and each of the light emitting elements of the second subset is operable to produce a respective light beam that is less diffuse than the light beams produced by the first subset of light emitting elements;
one or more optical elements disposed so as to project the light beams produced by the first and second subsets of light emitting elements onto a scene; and
control circuitry operable to control respective durations for which the light emitting elements of the first and second subsets are on so that a resulting overall illumination projected onto the scene is substantially homogenous diffuse illumination.

2. The apparatus of claim 1 wherein the light emitting elements of the first and second subsets, and the one or more optical elements, are disposed such that the light beams produced by the second subset are projected onto the scene so as to at least partially fill gaps in illumination produced by the first subset of light emitting elements.

3. The apparatus of claim 1 wherein the control circuitry is operable to turn on the light emitting elements of the first subset for a first duration, and to turn on the light emitting elements of the second subset for a second duration while the light emitting elements of the first subset are on, wherein the second duration is shorter than the first duration.

4. The apparatus of claim 1 wherein each of the first and second subsets of light emitting elements is composed of VCSELs.

5. The apparatus of claim 4 wherein the VCSELs of the first subset have a first aperture, and the VCSELs of the second subset have a second aperture, wherein the first aperture is larger than the second aperture.

6. The apparatus of claim 4 wherein the VCSELs of the first subset have a rectangular aperture.

7. The apparatus of claim 4 wherein the VCSELs of the first subset have a hexagonal aperture.

8. The apparatus of claim 4 wherein the VCSELs of the first subset have an aperture shaped differently from a shape of an aperture of the VCSELs of the second subset.

9. The apparatus of claim 1 wherein the control circuitry is operable to turn on the second subset of light emitting elements in a second mode of operation to project a structured light pattern onto the scene.

10. A method comprising:
turning on a first subset of light emitting elements and projecting diffuse illumination onto a scene using light produced by the first subset of light emitting elements; and
employing temporal light stitching to at least partially fill gaps in the diffuse illumination by turning on a second subset of light emitting elements and projecting light produced by the second subset of light emitting elements onto the scene, wherein the second subset of light emitting elements is on for a shorter duration than the first subset of light emitting elements.

11. The method of claim 10 wherein each of the first and second subsets of light emitting elements is composed of VCSELs.

12. The method of claim 10 wherein the VCSELs of the first subset have an aperture shaped differently from a shape of an aperture of the VCSELs of the second subset.

13. The method of claim 10 wherein the VCSELs of the first subset have an aperture sized differently from a size of an aperture of the VCSELs of the second subset.

14. The method of claim 10 further including turning on a third subset of light emitting elements and projecting light produced by the third subset of light emitting elements onto the scene, wherein the third subset of light emitting elements is on for a duration shorter than the first subset of light emitting elements, and wherein the light produced by the third subset and projected onto the scene at least partially fills additional gaps in the diffuse illumination.

15. The method of claim 14 wherein the third subset of light emitting elements is on for a duration that differs from the duration for which the second subset of light emitting elements in on.

16. An apparatus comprising:
an array of VCSELs, wherein each of the VCSELs has a rectangular or hexagonal aperture, each of the VCSELs being operable to produce a respective light beam; and
one or more optical elements disposed so as to project the light beams onto a scene;
wherein, for a particular working distance, when the VCSELs in the array are on, a substantially gap-free homogenous diffuse illumination is projected onto the scene.

17. The apparatus of claim 16 wherein each of the VCSELs has a square aperture.

18. The apparatus of claim 16 wherein each of the VCSELs has a hexagonal aperture.

19. The apparatus of claim 16 wherein, for the particular working distance, when the VCSELs in the array are on, there is no overlap between individual light beams produced by different ones of the VCSELs and projected onto the scene.

20. The apparatus of claim 2, wherein the control circuitry is operable to turn on the light emitting elements of the first subset for a first duration, and to turn on the light emitting elements of the second subset for a second duration while the light emitting elements of the first subset are on, wherein the second duration is shorter than the first duration, wherein:
each of the first and second subsets of light emitting elements is composed of VCSELs, the VCSELs of the first subset have a first aperture,
the VCSELs of the second subset have a second aperture, and
the first aperture is larger than the second aperture.
